(19) United States
(12) Patent Application Publication
(10) Pub. No.: US 2025/0379023 A1
(43) Pub. Date: Dec. 11, 2025

(54) GRANULAR SPUTTER SOURCE TARGET WITH REPELLER CUP AND METHOD FOR USE THEREOF

(71) Applicant: Axcelis Technologies, Inc., Beverly, MA (US)

(72) Inventors: Joshua ABESHAUS, Beverly, MA (US); Neil BASSOM, Beverly, MA (US); Makita ERNI, Beverly, MA (US); Scott GALICA, Beverly, MA (US)

(73) Assignee: Axcelis Technologies, Inc., Beverly, MA (US)

(21) Appl. No.: 19/172,784

(22) Filed: Apr. 8, 2025

Related U.S. Application Data
(60) Provisional application No. 63/631,513, filed on Apr. 9, 2024.

(51) Int. Cl. H01J 37/08; H01J 37/317

(52) U.S. Cl. CPC H01J 37/08; H01J 37/3171; H01J 2237/081

(57) ABSTRACT

The disclosure is generally directed to an ion implantation system and an ion source material associated therewith. More particularly, the present disclosure is directed to components for ion implantation system using an aluminum-based solid source material to produce ions for electrically doping silicon, silicon carbide, or other semiconductor substrates (i.e., wafer). The disclosed embodiments may be used at temperatures ranging up to 1000° C. The disclosed principles minimize deposits on extraction electrodes and source chamber components when using a pre-mixed etchant gas.

The instant application claims priority to the Non-Provisional Application Ser. No. 63/631,513 filed Apr. 9, 2025, the entirety of which are incorporated herein in its entirety.

### FIELD

The present invention relates generally to ion implantation systems, and more specifically to an ion implantation system configured to generate an ion beam comprising aluminum ions.

### BACKGROUND

There is increasing demand for ion implants using metal ions. For example, aluminum (Al) implants are important for the power device market. For many metals, including aluminum, supplying feed material to the ion source is challenging. Systems have been previously provided that utilize a vaporizer, which is a small oven external to the arc chamber of the ion source, whereby metal salts are heated to produce adequate vapor pressure to supply vapor to the ion source. The oven, however, is remote from the arc chamber and takes time to heat up to the desired temperature, establish the vapor flow, start the plasma, start the ion beam, etc. Further, if a change from one metal species to some other species is desired, time is spent waiting for the oven to cool down adequately for such a change in species.

Another conventional technique is a sputtering technique in which a metal-containing material (e.g., aluminum) is placed inside the arc chamber. The metal-containing material conventionally comprises a monolithic solid material. For aluminum, the metal-containing material may comprise aluminum oxide, aluminum fluoride, or aluminum nitride, all of which can withstand the approximately 800° C. temperatures of the plasma chamber. In such a system, ions are sputtered directly off the material in the plasma. Another technique is to use a plasma containing an etchant such as fluorine to attain chemical etching of the metal. While acceptable beam currents can be attained using these various techniques, compounds of aluminum oxide, aluminum chloride, and aluminum nitride, all of which are good electrical insulators, tend to be deposited on electrodes adjacent to the ion source in a relatively short period of time (e.g., 5-10 hours). As such, various deleterious effects are seen, such as high voltage instabilities and associated variations in dosage of ions being implanted.

Thus, there is a need for an improved system, method and apparatus to enable Al ion source operation.

### SUMMARY OF THE DISCLOSURE

The disclosure is generally directed to an ion implantation system and an ion source material associated therewith. More particularly, the present disclosure is directed to components for ion implantation system using a metal-based source material to produce ions for electrically doping silicon, silicon carbide, or other semiconductor substrates (i.e., wafer). The metal-based source material may be in the metal-coated ceramic granules. In one embodiment, the granules comprise metal-containing ceramic. The granules may have different shapes as described below. The disclosed embodiments may be used at temperatures ranging up to 1000° C. The disclosed principles minimize deposits on extraction electrodes and source chamber components when using a pre-mixed etchant gas. The etchant gas may comprise predetermined mixture of fluorine and a noble or inert gas. An exemplary inert gas is helium. Among others, the present disclosure provides an advantageous temperature profile, reduces source operating pressure, increases etch rates of the aluminum-containing material. These advantages can expedite the ionization process and increase the instrument's lifespan.

In one embodiment, the disclosure relates to an ion source apparatus, comprising: an ion source chamber having a housing and an extraction aperture; a cathode electrode disposed within the housing, the cathode electrode configured to inject electrons into the chamber once heated; and a repeller positioned proximal to the radiation source, the repeller comprising a receptacle to receive a metal based source material, the metal based source material further comprising a plurality of metal-containing ceramic granules; wherein the plurality of metal-containing ceramic granules are positioned to contact a free flow of an etchant gas introduced into the housing to thereby generate a plurality of metal ions within the ion source chamber.

In another embodiment, the disclosure relates to a method for generating ions for an implantation system, the method comprising: energizing a metal based source material at an ion source chamber having a housing and an extraction aperture, the metal based source material further comprising a plurality of metal-containing ceramic granules; supplying an etchant gas to the ion source chamber, the etchant gas further comprising a mixture of fluorine gas mixed with a noble gas; supplying a feed gas to the ion source chamber, the feed gas source configured to ionize the metal-containing ceramic granules to form an ion beam therefrom; transporting the ion beam from the extraction aperture through a beamline assembly.

### BRIEF DESCRIPTION OF THE DRAWINGS

Certain disclosed embodiments will now be described with reference to an exemplary ion implantation system as depicted in the accompanying figures, in which like reference numerals may be used to refer to like elements throughout. It should be understood that the description of these aspects is merely illustrative and nonlimiting. In the following description, for purposes of explanation, numerous specific details are set forth in order to provide a thorough understanding of the present invention. It will be evident to one skilled in the art, however, that the present invention may be practiced without some of these specific details. The drawings include:

FIG. 1 illustrates an exemplary vacuum system according to one embodiment of the disclosure;

FIG. 2 schematically illustrates an exemplary environment for implementing the disclosed principles;

FIG. 3 schematically illustrates a repeller according to one embodiment of the disclosure;

FIG. 4A is a schematic illustration of an exemplary repeller mounted in an arc chamber according to one embodiment of the disclosure;

FIG. 4B is a schematic illustration of an exemplary source material in a substantially spherical form; and

FIG. 5 illustrates an exemplary ion implantation method according to one embodiment of the disclosure.

### DETAILED DESCRIPTION

In the following description, for purposes of explanation, numerous specific details are set forth in order to provide a thorough understanding of the invention. It will be apparent, however, to one skilled in the art that the invention may be practiced without these specific details. In other instances, structure and devices are shown in block diagram form in order to avoid obscuring the invention. References to numbers without subscripts or suffixes are understood to reference all instances of subscripts and suffixes corresponding to the referenced number. Moreover, the language used in this disclosure has been selected principally for readability and instructional purposes and may not have been selected to delineate or circumscribe the inventive subject matter, resort to the claims being necessary to determine such inventive subject matter. Reference in the specification to “one embodiment” or to “an embodiment” means that a particular feature, structure, or characteristic described in connection with the embodiments is included in at least one embodiment of the invention, and multiple references to “one embodiment” or “an embodiment” should not be understood as necessarily all referring to the same embodiment.

The embodiments described herein are examples and for illustrative purposes. Persons of ordinary skill in the art will recognize that alternative techniques for implementing the disclosed subject matter may be used. Elements of example embodiments may be arranged in different arrangements or combined with elements of different example embodiments. For example, the order of execution of blocks and flow charts may be changed. Some of the blocks of those flowcharts may be changed, eliminated, or combined and other blocks may be added as desired.

The disclosure is generally directed to an ion implantation system and an ion source material associated therewith. Particularly, the present disclosure is directed to components for ion implantation system using a metal-based source material to produce ions for electrically doping silicon, silicon carbide, or other semiconductor substrates (i.e., wafer). The metal-based source material may be in the metal-coated ceramic granules. The granules may have different shapes as described below. The disclosed principles provide a favorable thermal profile from the aggregate of the metal-coated ceramic granules and minimize deposits on extraction electrodes and source chamber components when using a pre-mixed etchant gas. The etchant gas may comprise predetermined mixture of fluorine and a noble or inert gas. An exemplary inert gas is helium. Among others, the disclosure reduces source operating pressure, increases etch rates and minimizes the sputter rate of the metal-containing material. These advantages can expedite the ionization process and increase the instrument's lifespan.

Ion implantation is a physical process and is employed in semiconductor device fabrication to selectively implant dopant into a wafer material. The wafer material is typically a semiconductor based substance. Implantation does not rely on a chemical interaction between a dopant and semiconductor material. During the ion implantation process, dopant atoms/molecules from an ion source of an ion implanter (or source material) are ionized, accelerated, formed into an ion beam, analyzed, and swept across a wafer, or the wafer is translated through the ion beam. Ion sources typically generate the ion beam by ionizing a source material in an arc chamber, wherein a component of the source material is a desired dopant element. The desired dopant element is then extracted from the ionized source material in the form of the ion beam. The dopant ions physically bombard the wafer to enter the surface and come to rest below the surface at a depth related to their energy.

When aluminum ions are the desired dopant element, materials such as aluminum nitride (AlN) and alumina (Al₂O₃) are often used as the source material for aluminum ions. Aluminum nitride or alumina are solid, insulative materials which are typically placed in the arc chamber where the plasma is formed (in the ion source).

A gas (e.g., fluorine (F₂)) is introduced to chemically etch the aluminum-containing source material. The etchant ionizes the source material and aluminum is extracted and transferred along the beamline to a workpiece (e.g., silicon carbide) positioned in an end station. The aluminum-containing materials, for example, are commonly used with some form of fluorine-based etchant gas (e.g., BF₃, PF₃, NF₃, SiF₄, SF₆, etc.) in the arc chamber as the source material of the aluminum ions. These materials, however, may have the side effect of producing insulating material (e.g., AlN, Al₂O₃, AlF₃, etc.) which is emitted along with the intended aluminum ions from the arc chamber. The insulating material may subsequently coat various components of the ion source, such as extracting electrodes, which then begin to build an electric charge and diminish the electrostatic characteristic of the extraction electrodes. The consequence of the electric charge build-up results in behavior commonly referred to as arcing, or “glitching”, of the extraction electrodes as the built-up charge arcs to other components and/or to ground.

During implementation, the source material must be heated to a desired temperature before the etchant can engage in the desired reaction. The rate at which the source material reaches and maintains the desired temperature can directly affect ion beam formation efficiency. Conventional source material comprise a monolithic solid mass which contains the desired dopant metal(s) and is heated in the arc chamber prior to etching. The arc chamber is maintained at vacuum pressure and the heating of the source material occurs predominantly through radiation. The thermal profile of the monolithic solid mass dictates the source material's temperature profile for heating and cooling and since the source material's temperature dictates the reaction rate, the source material temperature profile directly impacts the ion beam formation process. Conventional methods introduce inefficiencies to the etching process as a result of their unfavorable temperature profile.

The disclosed embodiments provide a novel apparatus, system and method to provide an advantageous heating profile for the source material to thereby enhance the etching process. In one embodiment, the metal-coated ceramic granules are used as the source material to provide an advantageous thermal profile as well as to increase the reactive surface area of the etchant material.

In one embodiment, the source material is selected and shaped to provide a more rapid heating of the top surface of the source material. For example, the source material may be selected from solid material of varying shapes to provide a generally stratified heating profile. The source material may comprise metal-containing ceramic granules having varying shapes including balls, cylinders, cubes, shards or combinations thereof. The heating and cooling profile of a mass of granules differs from that of a solid source material and has been found to be more advantageous for use in an ion source chamber. Because the granules conduct heat exclusively through their contact points with each other, the heat transfer rate between the granules is a function of the contact points' surface area. This results in faster heating of the top layer(s) and slower cooling of the entire mass of granules.

In some applications, the granules are placed in a receptacle and exposed to radiation and the etchant material. The target material is also exposed to the plasma. The ions from the plasma hitting the target can be a significant source of heat. Exposure to radiation and plasma cause the top layer of granules (i.e., top strata) to arrive at the reaction temperature before than the lower layers of granules. The lower strata of granules will heat predominantly through conduction heating from the top strata and exposure to plasma ions. This conduction profile defines a substantially stratified profile in which the top strata will reach the reaction temperature quicker than the adjacent layers. Conversely, due to the reduced conduction between the granules, the receptacle will maintain its temperature longer than the conventional solid etchant material.

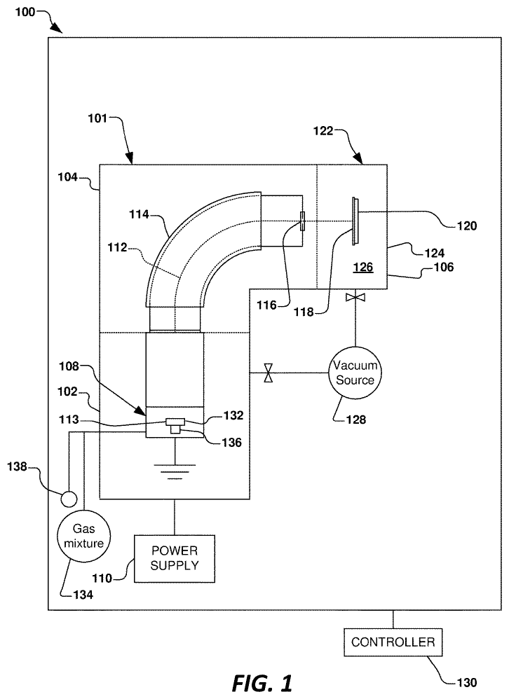

FIG. 1 illustrates an exemplary vacuum system according to one embodiment of the disclosure. Vacuum system 100 comprises an ion implantation system 101. Various types of vacuum systems (e.g., plasma processing systems) may be implemented without departing from the disclosed principles. Ion implantation system 101 comprises terminal 102, beamline assembly 104, and end station 106.

Ion source 108 in terminal 102 is coupled to a power supply 110 to ionize a dopant gas into a plurality of ions from the ion source to form an ion beam 112. Individual electrodes (not shown) in close proximity to the extraction electrode (not shown) may be biased to inhibit back streaming of neutralizing electrons close to the source or back to the extraction electrode. Ion source material 113 of the present disclosure is provided in ion source 108, wherein the ion source material may comprise an aluminum-based source material such as solid aluminum oxide (Al₂O₃), aluminum nitride (AlN) or other aluminum-containing material.

Ion beam 112 may be directed through a beam-steering apparatus 114, and out aperture 116 towards end station 106. Ion beam 112 bombards workpiece 118 (e.g., a semiconductor such as a silicon wafer, a display panel, etc.) at end station 106. Workpiece 118 may be selectively clamped or mounted to a chuck 120 (e.g., an electrostatic chuck or ESC). Once embedded into the lattice of the workpiece 118, the implanted ions change the physical and/or chemical properties of the workpiece.

Ion beam 112 can take any form, such as a pencil or spot beam, a ribbon beam, a scanned beam, or any other form in which ions are directed toward end station 106. End station 106 comprises process chamber 122 which includes vacuum chamber 124. Process environment 126 generally exists within process chamber 122, and in one example, comprises vacuum produced by vacuum source 128 (e.g., a vacuum pump) coupled to the process chamber and configured to substantially evacuate the process chamber. Controller 130 is provided for overall control of the vacuum system 100.

In one embodiment, the disclosure contemplates ion source material 113, for example, as being an aluminum-based ion source material 132. Etchant gas mixture 134 is provided, whereby an introduction of the etchant gas mixture advantageously provides high ion beam currents with minimal deleterious issues associated with the higher pressures associated larger molecular mass materials further amplifying the negative effects due to the formation of either insulating and or and conductive materials discussed above. It should be noted that the etchant gas may comprise a mixture of gases. For example, etchant gas mixture 134 may comprise fluorine up to the predetermined health safety level (e.g., approximately 20%), while the remainder of the etchant gas mixture comprises an inert, noble, or other non-reactive gas, such as helium (He), argon (Ar), krypton (Kr), xenon (Xe), or the like. The co-gas 138 may be provided with the helium and fluorine in the etchant gas mixture 134 for sputtering an aluminum-based ceramic granules.

In one example, the disclosure contemplates the aluminum-based ion source material 132 as comprising aluminum oxide (Al₂O₃) or aluminum nitride (AlN) to produce atomic aluminum ions in conjunction with the etchant gas mixture 134, wherein the etchant gas mixture comprises a non-reacted mixture of a predetermined percentage of fluorine along with a noble or inert gas.

Exemplary reactions of the aluminum source material and the fluorine-based etchant include:

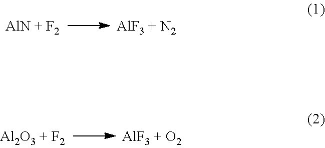

For example, the aluminum-based ion source material 132 may be incorporated into a ceramic composition and held at member 136 (e.g., a Repeller, shield or porous cover, or other container within ion source 108), wherein the ceramic is sputtered or etched using the fluorine gas from the etchant gas mixture 134 according to, for example, equations (1) and (2). The aluminum-based ion source material 132 can undergo high temperature processes of 1000° C. or higher whereby the ceramic composition can withstand such temperatures without melting.

Etchant gas may comprise a mixture of gases. For example, etchant gas mixture 134 may comprise fluorine up to the predetermined health safety level (e.g., approximately 20%), while the remainder of the etchant gas mixture comprises an inert, noble, or other non-reactive gas, such as helium (He), argon (Ar), krypton (Kr), xenon (Xe), or the like.

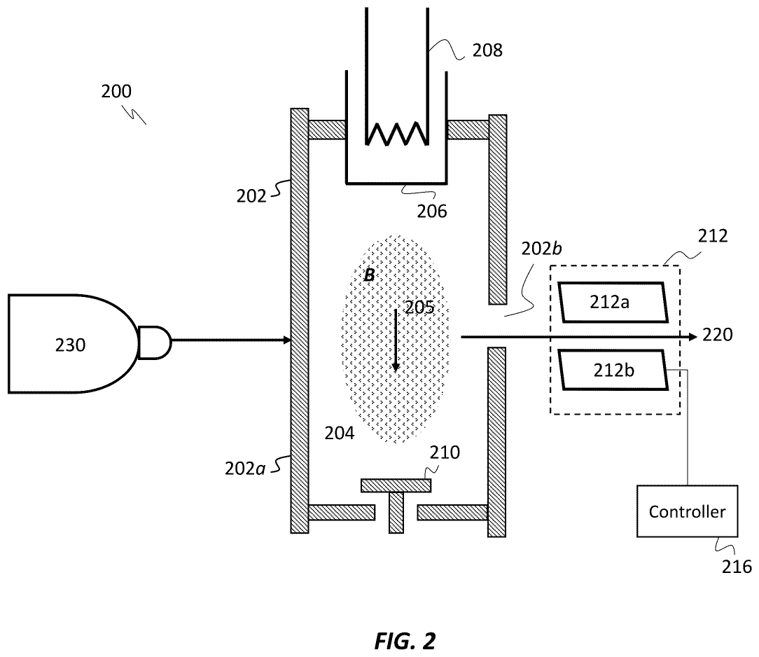

FIG. 2 schematically illustrates an exemplary environment for implementing the disclosed principles. Specifically, FIG. 2 illustrates an indirectly heated cathode (IHC) ion source 200 and extraction system 212 which may be used to implant dopants. The exemplary ion source 200 is illustrated with ion source chamber 202 comprising one or more conductive chamber walls 202a defining an ion generation region 204. Ion source chamber 202 also includes an extraction aperture 202b which may define a slit or an aperture. At one side of the ion source chamber 202, there may be a cathode 206 and filament 208 which provide radiation heating to the chamber. Cathode 206 is the source of electrons and once heated, the cathode will radiate to inject electrons (plasma) 205 into the region 204 as discussed below. Repeller 210 may be positioned opposite cathode 206. A feed source 230 containing feed gas may be coupled to ion source chamber 202. The feed gas material may contain desired etchant gas and/or dopant species. In one embodiment, the feed material may further comprise a diluent to dilute the feed material.

Extraction system 212 may be positioned near extraction aperture 202b of ion source chamber 202. Extraction system 212 may comprise suppression and ground electrodes, which for simplicity, are represented as electrodes 212a and 212b. The electrodes may be electrically coupled to power supply and controller 216. Electrodes 212a, 212b may comprise an aperture aligned with the extraction aperture 202b for extraction of the ions 220 from the ion source chamber 202.

In operation, feed gas may be introduced into the ion source chamber 202 from source 230. Filament 208, which may be coupled to a power supply (not shown), is activated. The current supplied to filament 208 may heat the filament and cause thermionic emission of electrons from filament 208 and cathode 206. Cathode 206, which may be coupled to another power supply (not shown), may be biased at much higher potential relative to the filament 208 and significantly lower than chamber 202. The electrons emitted from filament 208 are accelerated toward and heat the cathode 206. Heated cathode 206, in response, may emit electrons toward region 204 as schematically illustrated by the arrow. Chamber walls 202a may also be biased with respect to cathode 106 so that the electrons are accelerated at a high energy into ion generation region 204. A source magnet (not shown) may create a magnetic field B inside ion generation region 204 to confine the energetic electrons 205, and the repeller 210 at the other end of the ion source chamber 202 may be biased at a same or similar potential as the cathode 206 to repel the energetic electrons.

Within ion generation region 204, energetic electrons may interact and ionize the feed material to produce plasma containing, among others, ions of desired species 220 (e.g., desired dopants or impurities). The plasma may be generally concentrated at region 205. The extraction power supply 216 provides extraction voltage to ground electrode 212b for extracting the ion beam 220 from ion source chamber 202. The extraction voltage may be adjusted according to the desired energy of the ion beam 200.

As discussed, using granules as the source material increases the reactive surface area in the ion source chamber. The granules also provide a more effective temperature profile as the top layer of granules will reach higher temperatures than the lower layers. The top layer of the metal-containing granules will also reach a higher temperature than if a monolithic solid source material.

In certain embodiments, the disclosure uses a metal-based ceramic as a target for chemical etching/sputtering to generate metal ions inside the arc chamber. A vaporizer may or may not be used. The metals include, but are not limited to, Al, In, Sb, or others. In one implementation, a cup containing a collection of captive ceramic pieces (granules) may be used in place of a conventional repeller. The metal-based ceramic pieces may comprise any shape including, but not limited to, balls, cylinders, cubes, shards or combinations thereof. The metal-based ceramic pieces may be substantially covered with a metal coating to provide ionization reaction surfaces. The metal-based ceramic pieces serve as a source of metal ions and increase the surface area of exposed ceramic granules while allowing for free flow of etchant gas through a repeller cup (or container) volume. The granules also provide many edges and small contact points between the ceramic and the Repeller body. These contact points act as areas for E-field and temperature concentration which can increase etch rate at these locations.

In an exemplary embodiment, the metal-coated ceramic granules may comprise a coating thickness of about 50-500 microns. In another embodiment, the coating thickness may be in the range of about 50-100 microns, 100-200 microns, 200-300 microns, 300-400 microns, 400 to 500 microns or any range in between. Coating thickness of below or above these ranges may be applied without departing from the disclosed principles.

In one embodiment, a cup shaped repeller is filled with granules of ceramic beads, balls, balls, cylinders or shards. A porous cover (e.g., a mesh, a plate with holes) may be used to retain the ceramic granules inside the repeller housing. Exemplary repeller material may include tungsten (W) or graphite, for example. The porous cover may comprise tungsten. The ceramic granules may be coated with Al₂O₃, AlN or other metal-containing source material.

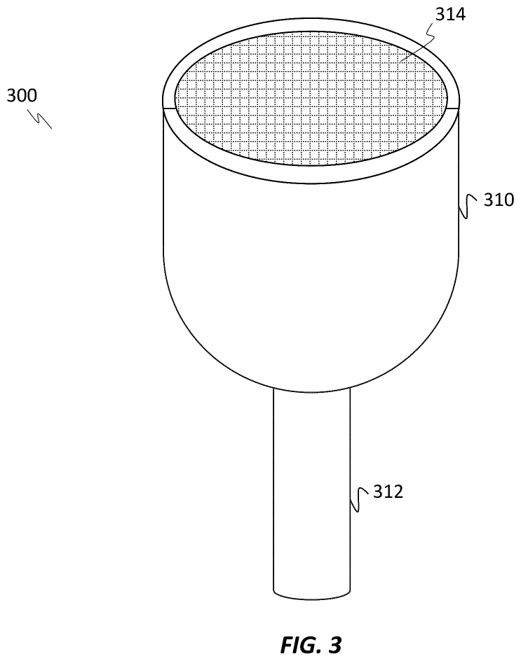

FIG. 3 schematically illustrates a repeller according to one embodiment of the disclosure. In FIG. 3, repeller 300 includes receptacle 310 coupled to handle 312. Receptacle 310 may define a cavity to receive metal-coated ceramic granules (not shown) according to one embodiment of the disclosure. The top opening of repeller 300 may optionally include a porous cover 314 to retain the ceramic granules inside the receptacle. Handle 312 may be configured for coupling to a housing the inside or the outside of the arc chamber (not shown in FIG. 3).

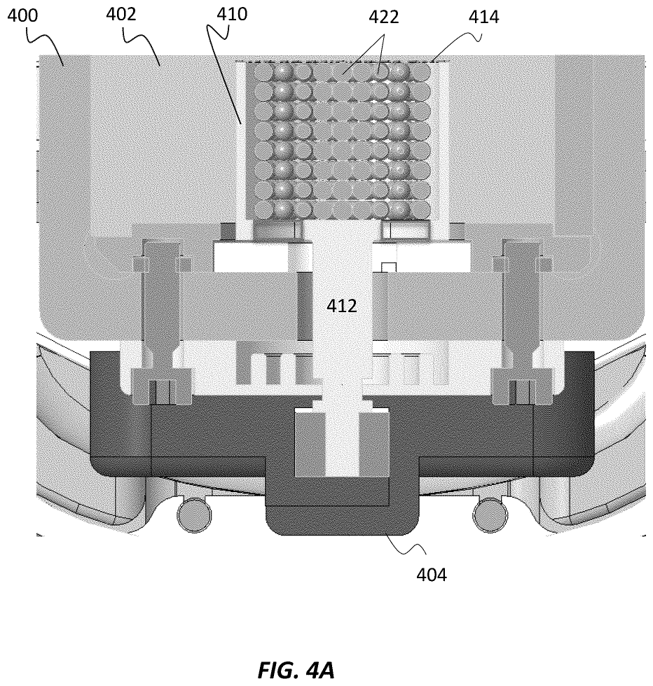

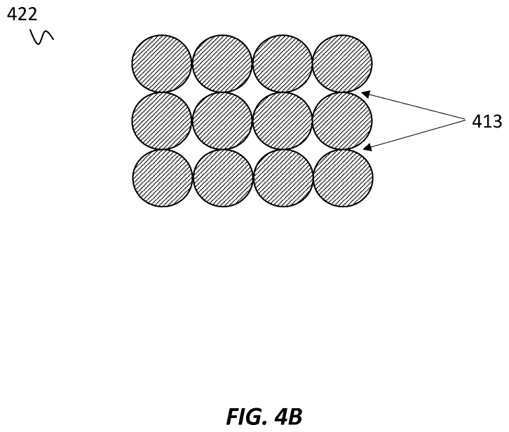

FIG. 4A is a schematic illustration of an exemplary repeller mounted in an arc chamber (e.g., ion source chamber 202, FIG. 2) according to one embodiment of the disclosure. Repeller 410 is seated at housing 402 inside arc chamber 400. Repeller 410 comprises handle 412 which is received at the base 404 of housing 402. Metal containing-ceramic granules 422 are shown to fill the inside cavity of repeller 410. While the schematic illustration of FIG. 4 shows the granules as spherical, it should be noted that the granules' shape is not limited thereto and may comprise balls, cylinders, cubes, shards or combinations thereof. In one embodiment, the granules define non-geometric or asymmetric shapes. Porous cover 414 is placed over repeller 410 to retain granules 422 in the cavity of the repeller.

The embodiment of FIG. 4B represents an exploded view of a portion of the granules 422 of FIG. 4A. Here, each of the spherical metal coated ceramic granules 422 contacts at least one other granule through a contact point 413. The size of the contact point is dictated and limited by the surface area of the contact point. Heat transmission from one spherical granule to an adjacent granule is limited to the surface area of the contact point 413. As a result, the heat conduction profile of the granules 422 filling repeller 410 is different than a repeller filled with a solid monolithic coated material. In FIG. 4B, the limited conduction between the top strata of metal coated ceramic granules 422 will cause the top layer to heat rapidly due to its exposure to the radiation source (e.g., heating cathode 206, FIG. 2). Because repeller 410 is placed in a vacuum environment (i.e., chamber 202, FIG. 2), heat transfer is limited to radiation and conduction. The heating of the lower granule strata will be substantially limited conduction from the upper granule layers. The limitation results in a slower heating and cooling of the lower strata granules thereby creating a unique thermal profile that increases the etch rate at the uppermost surface.

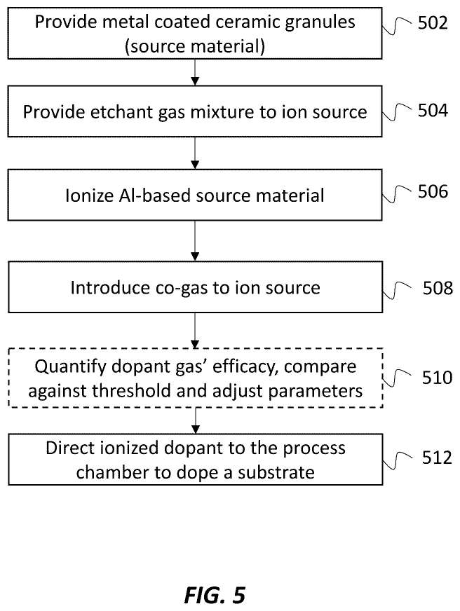

FIG. 5 illustrates an exemplary ion implantation method according to one embodiment of the disclosure. It should be further noted that while exemplary methods are illustrated and described as a series of operations or steps, the disclosed principles are not limited thereto and the ordering of such operations may vary without departing from the disclosed principles. In addition, not all illustrated operations may be required to implement the disclosed methodology. It will be appreciated that the disclosed method may be implemented in association with the systems illustrated and described herein as well as in association with other systems not illustrated. The operations of FIG. 5 may be implemented as a software algorithm on a control system operating on an ion implantation system as discussed herein. In an exemplary embodiment, the software algorithm may be stored at a memory circuitry in communication with a processor circuitry. The memory circuitry may store instructions to cause the processor circuitry to act on the ion implementation system in accordance with certain of the disclosed principles.

At operation 502 of FIG. 5, a source material is provided. The aluminum-based ion source material, for example, may be a metal-containing ceramic granules having the desired etch material. The metal-containing ceramic granules (e.g., aluminum-containing ceramic (or ceramic coated with metal) may be positioned inside an arc chamber (e.g., chamber 202 of FIG. 2). In one embodiment, the granules are positioned inside a repeller with a mesh covering the open end of the repeller (e.g., repeller 300, FIG. 3).

At operation 504, an etchant gas mixture is provided to the ion source. The etchant gas mixture may comprise a predetermined concentration of fluorine mixed with a noble gas such as helium. Additional diluent gases may be included in the fluorine mixture. In operation 506, the metal covered ceramic granules (i.e., aluminum-based ion source material) are ionized in the ion source, wherein the fluorine etches the aluminum-based ion source material within the ion source to produce aluminum ions. In operation 508, a co-gas, such as argon, is introduced to the ion source to sputter the metal-coated ceramic granules.

At operation 510 (optional), the resultant ion stream (beam) may be quantified and compared to existing threshold to determine whether it is within an acceptable range. If the beam is not within a predefined range, the operating parameters (e.g., temperature, pressure, etc.) may be changed to bring the beam within the acceptable range. Finally, at operation 512, the ionized dopant (beam) is directed to the process chamber to dope a substrate (i.e., wafer). Additional process control and quantification may be implemented without departing from the disclosed principles.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments but is intended to be limited only by the appended claims and equivalents thereof.

### EXEMPLARY EMBODIMENTS

The following non-limiting and exemplary embodiments are provided to further illustrate applications of the disclosed principles.

Example 1 relates to an ion source apparatus, comprising: an ion source chamber having a housing and an extraction aperture; a cathode electrode disposed within the housing, the cathode electrode configured to inject electrons into the chamber once heated; and a repeller positioned proximal to the radiation source, the repeller comprising a receptacle to receive a metal based source material, the metal based source material further comprising a plurality of metal-containing ceramic granules; wherein the plurality of metal-containing ceramic granules are positioned to contact a free flow of an etchant gas introduced into the housing to thereby generate a plurality of metal ions within the ion source chamber.

Example 2 relates to the apparatus of example 1, wherein the metal-containing ceramic granules define shapes selected from the group consisting of balls, cylinders, cubes, shards or combinations thereof.

Example 3 relates to the apparatus of example 1, wherein the metal-containing based ceramic granules comprises aluminum, aluminum oxide, aluminum nitride or composites thereof.

Example 4 relates to the apparatus of example 3, wherein at least one metal-containing ceramic granule comprises a ceramic substrate coated with an aluminum composite to a thickness in the range of about 50 to 500 microns.

Example 5 relates to the apparatus of example 1, wherein the repeller further comprises a porous cover configured to captively contain the metal-containing ceramic granules and to permit the free flow of the etchant gas introduced into the receptacle.

Example 6 relates to the apparatus of example 5, wherein the porous cover comprises a mesh.

Example 7 relates to the apparatus of example 5, wherein the porous cover comprises a plate with a plurality of holes.

Example 8 relates to the apparatus of example 1, further comprising a co-gas for sputtering the metal based source material.

Example 9 relates to a method for generating ions for an implantation system, the method comprising: energizing a metal based source material at an ion source chamber having a housing and an extraction aperture, the metal based source material further comprising a plurality of metal-containing ceramic granules; supplying an etchant gas to the ion source chamber, the etchant gas further comprising a mixture of fluorine gas mixed with a noble gas; supplying a feed gas to the ion source chamber, the feed gas source configured to ionize the metal-containing ceramic granules to form an ion beam therefrom; transporting the ion beam from the extraction aperture through a beamline assembly.

Example 10 relates to the method of example 9, further comprising receiving the ion beam at an end station and implementing the ion beam onto a workpiece.

Example 11 relates to the method of example 9, wherein the plurality of metal-containing ceramic granules define shapes selected from the group consisting of balls, cylinders, cubes, shards or combinations thereof.

Example 12 relates to the method of example 9, wherein the metal based source material comprises aluminum, aluminum oxide, aluminum nitride or composites thereof.

Example 13 relates to the method of example 12, wherein at least one granule comprises a ceramic substrate coated with an aluminum composite to a thickness in the range of about 50 to 500 microns.

Example 14 relates to the method of example 9, wherein the housing further comprises a repeller with a non-electrode porous cover to permit free flow of the etchant gas introduced into an interior volume of the repeller.

Example 15 relates to the method of example 14, wherein the non-electrode porous cover comprises a mesh.

Example 16 relates to the method of example 9, further comprising sputtering and/or etching the metal based source material with a co-gas introduced into the ion source chamber.

Example 17 relates to the method of example 9, wherein the step of energizing a metal based source material further comprises radiating the metal based source material with an indirectly heating cathode.

While the principles of the disclosure have been illustrated in relation to the exemplary embodiments shown herein, the principles of the disclosure are not limited thereto and include any modification, variation or permutation thereof.

What is claimed is:

1. An ion source apparatus, comprising:
an ion source chamber having a housing and an extraction aperture;
a cathode electrode disposed within the housing, the cathode electrode configured to inject electrons into the chamber once heated; and
a repeller positioned proximal to the radiation source, the repeller comprising a receptacle to receive a metal based source material, the metal based source material further comprising a plurality of metal-containing ceramic granules;
wherein the plurality of metal-containing ceramic granules are positioned to contact a free flow of an etchant gas introduced into the housing to thereby generate a plurality of metal ions within the ion source chamber.

2. The apparatus of claim 1, wherein the metal-containing ceramic granules define shapes selected from the group consisting of balls, cylinders, cubes, shards or combinations thereof.

3. The apparatus of claim 1, wherein the metal-containing based ceramic granules comprises aluminum, aluminum oxide, aluminum nitride or composites thereof.

4. The apparatus of claim 3, wherein at least one metal-containing ceramic granule comprises a ceramic substrate coated with an aluminum composite to a thickness in the range of about 50 to 500 microns.

5. The apparatus of claim 1, wherein the repeller further comprises a porous cover configured to captively contain the metal-containing ceramic granules and to permit the free flow of the etchant gas introduced into the receptacle.

6. The apparatus of claim 5, wherein the porous cover comprises a mesh.

7. The apparatus of claim 5, wherein the porous cover comprises a plate with a plurality of holes.

8. The apparatus of claim 1, further comprising a co-gas for sputtering the metal based source material.

9. A method for generating ions for an implantation system, the method comprising:
energizing a metal based source material at an ion source chamber having a housing and an extraction aperture, the metal based source material further comprising a plurality of metal-containing ceramic granules;
supplying an etchant gas to the ion source chamber, the etchant gas further comprising a mixture of fluorine gas mixed with a noble gas;
supplying a feed gas to the ion source chamber, the feed gas source configured to ionize the metal-containing ceramic granules to form an ion beam therefrom;
transporting the ion beam from the extraction aperture through a beamline assembly.

10. The method of claim 9, further comprising receiving the ion beam at an end station and implementing the ion beam onto a workpiece.

11. The method of claim 9, wherein the plurality of metal-containing ceramic granules define shapes selected from the group consisting of balls, cylinders, cubes, shards or combinations thereof.

12. The method of claim 9, wherein the metal based source material comprises aluminum, aluminum oxide, aluminum nitride or composites thereof.

13. The method of claim 12, wherein at least one granule comprises a ceramic substrate coated with an aluminum composite to a thickness in the range of about 50 to 500 microns.

14. The method of claim 9, wherein the housing further comprises a repeller with a non-electrode porous cover to permit free flow of the etchant gas introduced into an interior volume of the repeller.

15. The method of claim 14, wherein the non-electrode porous cover comprises a mesh.

16. The method of claim 9, further comprising sputtering and/or etching the metal based source material with a co-gas introduced into the ion source chamber.

17. The method of claim 9, wherein the step of energizing a metal based source material further comprises radiating the metal based source material with an indirectly heating cathode.
